(19) United States
(12) Patent Application Publication
(10) Pub. No.: US 2013/0276872 A1
(43) Pub. Date: Oct. 24, 2013

(54) SOLAR CELL UNIT AND METHOD FOR MANUFACTURING THE SAME

(71) Applicants: Haizhou Yin, Poughkeepsie, NY (US); Huilong Zhu, Poughkeepsie, NY (US); Zhijiong Luo, Poughkeepsie, NY (US)

(72) Inventors: Haizhou Yin, Poughkeepsie, NY (US); Huilong Zhu, Poughkeepsie, NY (US); Zhijiong Luo, Poughkeepsie, NY (US)

(73) Assignee: SUNOVEL SUZHOU TECHNOLOGIES LTD., SUZHOU CITY (CN)

(21) Appl. No.: 13/864,503

(22) Filed: Apr. 17, 2013

(30) Foreign Application Priority Data
Apr. 19, 2012 (CN) 201210114584.6

(51) Int. Cl. H01L 31/0687; H01L 31/18

(52) U.S. Cl. CPC H01L 31/0687; H01L 31/1804
USPC 136/255; 438/57; 438/93

(57) ABSTRACT

A solar cell unit comprising a strip plate which has a third surface and a fourth surface opposite to the third surface, wherein a third doping region and a fourth doping region are arranged on the third surface and the fourth surface respectively, and a first doping region and a second doping region are arranged on side surfaces adjacent to the third surface and the fourth surface respectively; the types of impurities in the third doping region and the fourth doping region are contrary to one another; the surfaces of the first doping region and the second doping region have uniform doping type. Accordingly, the present invention further provides a method for manufacturing a solar cell unit.

This application claims priority to Chinese Application No. 201210114584.6, filed on Apr. 19, 2012. The Chinese Application is incorporated herein by reference in its entireties.

### FIELD OF THE INVENTION

The present invention relates to the technical field of solar cells, particularly, to a solar cell unit and a method for manufacturing the same.

### BACKGROUND OF THE INVENTION

Due to growing concern of energy shortage and environmental challenges, solar energy has been regarded as a potential solution. At the heart of the photovoltaic industry is a solar cell which converts photon energy to electrical energy. With rapid technological advancements in the photovoltaic industry, solar cells have been widely used in various applications.

As shown in FIG. 1, a solar cell unit in the prior art usually comprises a semiconductorplate 10 of p-type doped configuration or p-type doped configuration; a p+ doping region 20 is arranged on a primary surface of the semiconductor plate 10, while an p+ doping region 30 is arranged on another primary surface of the semiconductor plate 10. When a larger output voltage is needed, a plurality of solar cell units can be placed in series so as to achieve a large output voltage.

In practice, the solar cell unit in the prior art shows following disadvantages:

(1) photo-generated electrons and holes may be lost due to recombination at side surfaces of the solar cell unit (i.e. surfaces intersecting two primary surfaces of the solar cell units) resulting in degradation of energy conversion efficiency.

Consequently, side surfaces of the solar cell units have to be processed specifically to reduce carrier recombination at the side surfaces. A traditional process is to deposit SiN with positive body charges on the n-type doped surface and to deposit Al₂O₃ with negative body charges on the p-type doped surface, thereby reducing carrier recombination at surfaces of the solar cell. However, the side surfaces of the solar cell units usually have both n-type doped regions and p-type doped regions concurrently, which would make it unsuitable to apply the traditional process to reduce surface carrier recombination at both the n-type doped region and the p-type doped region at the same time;

(2) The two electrodes of a solar cell unit are usually formed on the front (i.e. light-absorbing) surface and the backside surface, respectively; the electrode on the light-absorbing surface blocks light and thus degrade energy conversion efficiency of the solar cell unit;
(3) a plurality of solar cell units arranged in series can increase output voltage; however, in case any one of the plurality of solar cell units is shielded from solar radiation, voltage generated on other solar cell units may drop at said solar cell unit in the shade, which consequently comes into reverse bias and causes the plurality of solar cell units in series not to output electrical energy effectively, since reverse electrical current in solar cell units is usually quite small. Besides, when the reverse bias is greater than the reverse breakdown voltage of a solar cell unit, the solar cell unit would be damaged. The conventional solution is to connect a bypass diode and solar cell units in parallel; in case a solar cell unit is in a shade and receives no light, other solar cell units placed in series can get around the dysfunctional solar cell unit through the bypass diode connected in parallel with the solar cell unit in a shade; in this way, other solar cell units connected in series can normally output electrical energy. Meanwhile, the reverse bias falling on the solar cell unit in a shade is limited to the turn-on voltage of the bypass diode, so as to avoid damage arising from reverse breakdown. However, this solution needs the use of an extra bypass diode, which consequently increases circuit complexity and manufacturing cost.

Accordingly, it is necessary to provide a solar cell unit and a method for manufacturing the same to solve some of the aforementioned problems.

### SUMMARY OF THE INVENTION

The present invention is intended to provide a solar cell unit and a method for manufacturing the same, such that side surfaces of the solar cell unit have uniform doping type, which is favorable for processing side surfaces of the solar cell unit so as to reduce carrier recombination at the surface area, and is also favorable for putting electrodes on side surfaces of the solar cell unit, which improves light absorption efficiency. Additionally, when the solar cell unit manufactured according to the present invention is at reverse bias, the reverse electrical current is greater than the reserve electrical current in traditional solar cell units, therefore it has the same effect of providing a build-in bypass diode, so as to make an extra bypass diode unnecessary.

In an aspect, the present invention provides a method for manufacturing a solar cell unit, which comprises following steps:

a) providing a substrate, which comprises a first surface and a second surface opposite to the first surface;
b) performing heavy doping to the first surface and the second surface respectively, so as to form a first doping region on the first surface and a second doping region on the second surface;
c) forming at least two first grooves and at least one second groove on the first surface and the second surface of the substrate; wherein, each of the second groove is located between two neighboring first grooves to form a vertical strip plate array comprising at least two strip plates and at least one sheet;
d) performing heavy doping to sidewalls of the first groove and the second groove respectively, so as to form a third doping region at the sidewall of the first groove and to form a fourth doping region at the sidewall of the second groove; and keeping the surface doping type of the first doping region and the second doping region unchanged, so as to form a vertical solar cell array; wherein the type of impurities in the third doping region is contrary to the type of impurities in the fourth doping region.

In another aspect, the present invention further provides a solar cell unit, which comprises a strip plate having a third surface and a fourth surface opposite to the third surface; wherein the third surface has a third doping region and the fourth surface has a fourth doping region; a first doping region and a second doping region are arranged on side surfaces adjacent to the third surface and the fourth surface, respectively; the type of impurities in the third doping region is contrary to the type of impurities in the fourth doping region; and the surfaces of the first doping region and the second doping region have the same doping type.

As compared to the prior art, the present invention exhibits following advantages:

(1) Instead of having two different doping types at side surfaces (i.e. a surface intersecting with elongated side of a solar cell unit) of a solar cell unit in the prior art, the solar cell unit provided according to the present invention has uniform doping type at its side surfaces; namely, the type of impurities in both side surfaces of the solar cell unit is either n-type or p-type, alternatively, a side surface has n-type doping impurities and the other side surface has p-type doping impurities. In this way, it effectively reduces difficulty experienced when processing side surfaces of solar cell unit;
(2) Since side surfaces of the solar cell unit are doped with uniform type of impurities, thus this configuration allows electrodes on side surfaces of the solar cell unit instead of forming electrodes on the light-absorbing surface of the solar cell unit as it does in prior art, and avoids to cast a shade onto the solar cell unit. Therefore, the solar cell unit manufactured according to the present invention provides improved light absorption efficiency and energy conversion efficiency;
(3) When the doping concentration meets certain conditions, the solar cell unit provided according to the present invention has a region (namely n+/p+ region) inside the solar cell unit where relatively highly n-type doped region and relatively highly p-type doped region situate adjacently closely to each other, which in this way forms a region analogous to a Zener diode; accordingly, when a reverse bias is present, the structure can allow flow of greater electrical current when the reverse voltage exceeds a certain value, so as to avoid reverse breakdown damage. When a plurality of solar cell units are operated in series, if any one of the plurality of solar cell units cannot work properly due to lack of solar radiation, the region analogous to a Zener diode structure (n+/p+ region) inside the solar cell units can guarantee that the entire serial circuit operates properly.

### BRIEF DESCRIPTION OF THE DRAWINGS

Other additional features, aspects and advantages of the present invention are made more evident according to perusal of the following detailed description of exemplary embodiment(s) in conjunction with accompanying drawings:

FIG. 1 shows a cross-sectional view of a solar cell unit in the prior art;

FIG. 2 shows a diagram of a method for manufacturing a solar cell unit according to an aspect of the present invention;

FIG. 3(a) and FIG. 3(b) show respectively a topview and a cross-sectional view of a substrate used in embodiments of the present invention;

FIG. 4(a) to FIG. 4(g) show cross-sectional views at each stage of forming a solar cell unit according to a preferred embodiment of the present invention; and

FIG. 5(a) and FIG. 5(g) show cross-sectional views at each stage of forming a solar cell unit according to another preferred embodiment of the present invention. The same or similar reference signs in the appended drawings denote the same or similar elements.

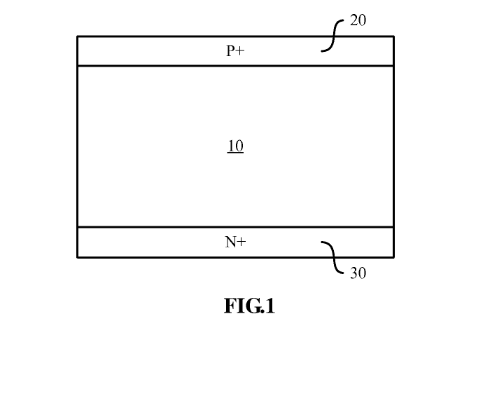

### DETAILED DESCRIPTION OF THE INVENTION

Embodiments of the present invention are to be described at length below, wherein examples of embodiments are illustrated in the appended drawings. It should be appreciated that embodiments described below in conjunction with the drawings are illustrative, and are provided for explaining the present invention only, thus shall not be interpreted as a limit to the present invention.

Various embodiments or examples are provided here below to implement different structures of the present invention. To simplify the disclosure of the present invention, descriptions of components and arrangements of specific examples are given below. They are only illustrative and not intended to limit the present invention. Moreover, in the present invention, reference numbers and/or letters may be repeated in different examples. Such repetition is for purposes of simplicity and clarity, yet does not denote any relationship between respective embodiments and/or arrangements under discussion. Furthermore, the present invention provides various examples for various processes and materials. However, it is obvious for a person of ordinary skill in the art that other processes and/or materials may be alternatively utilized. It should be noted that the appended drawings might not be drawn to scale. Description of the conventionally known elements, processing techniques and crafts are omitted from description of the present invention in order not to limit the present invention unnecessarily.

In additional, the expression “surface region” mentioned herein means a region away from the surface in the range of about 0 to 30 nm in terms of depth. The expression “surface doping” herein means doping at the surface region; accordingly, the expression “surface doping type” means the doping type at the surface region. Herein, “heavy doping” means doping carried out in such an intensity that the doping concentration at the surface region is at least higher than 1×10¹⁹ cm⁻³.

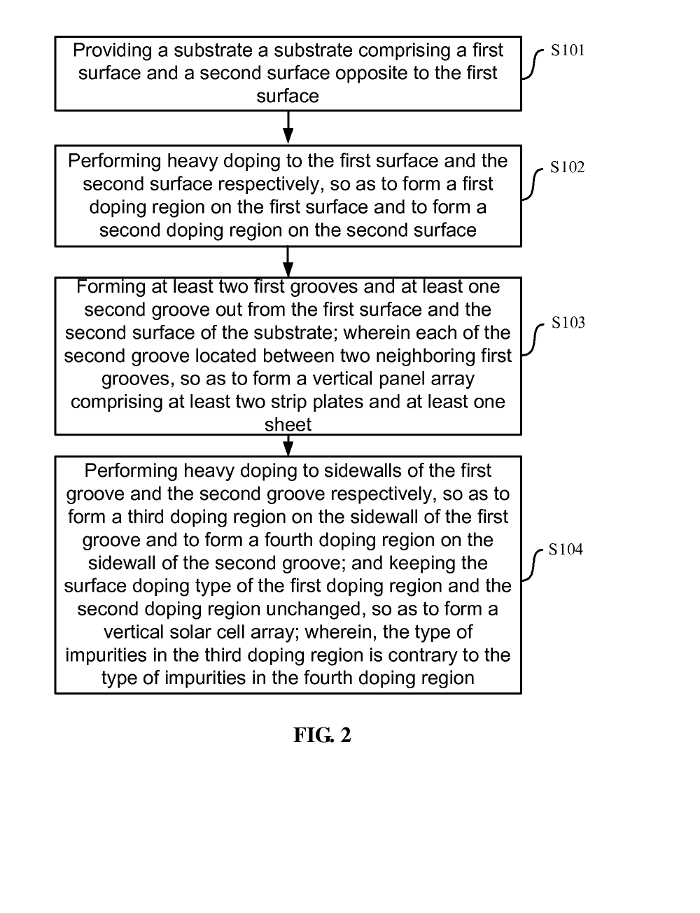

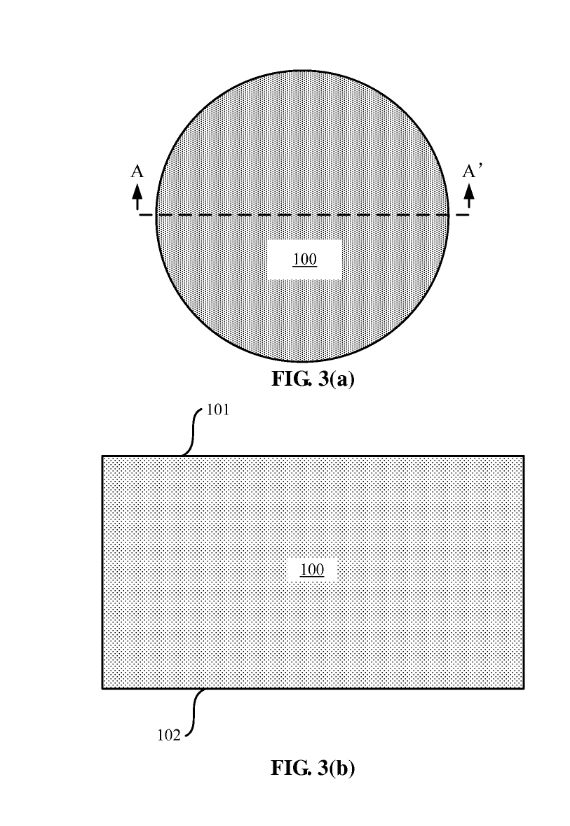

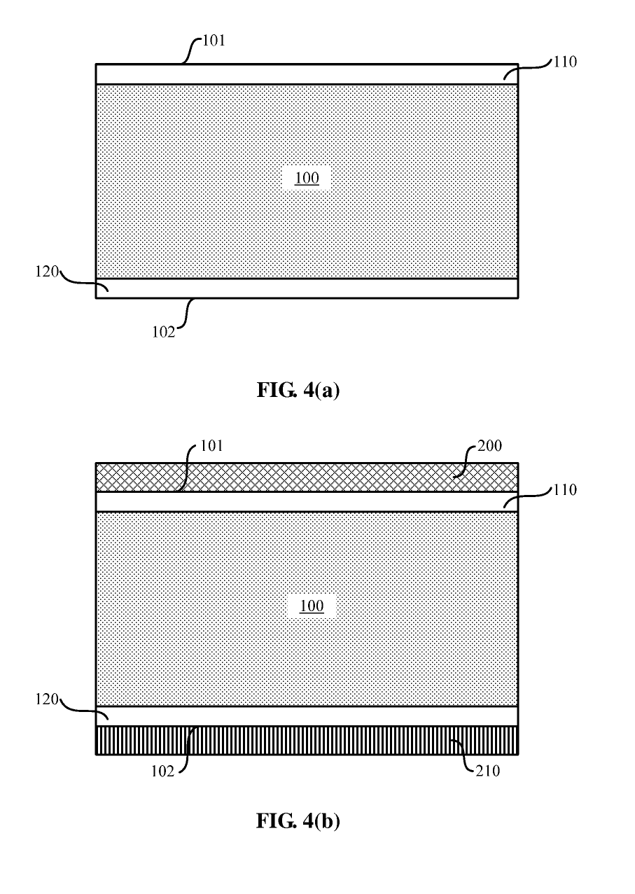

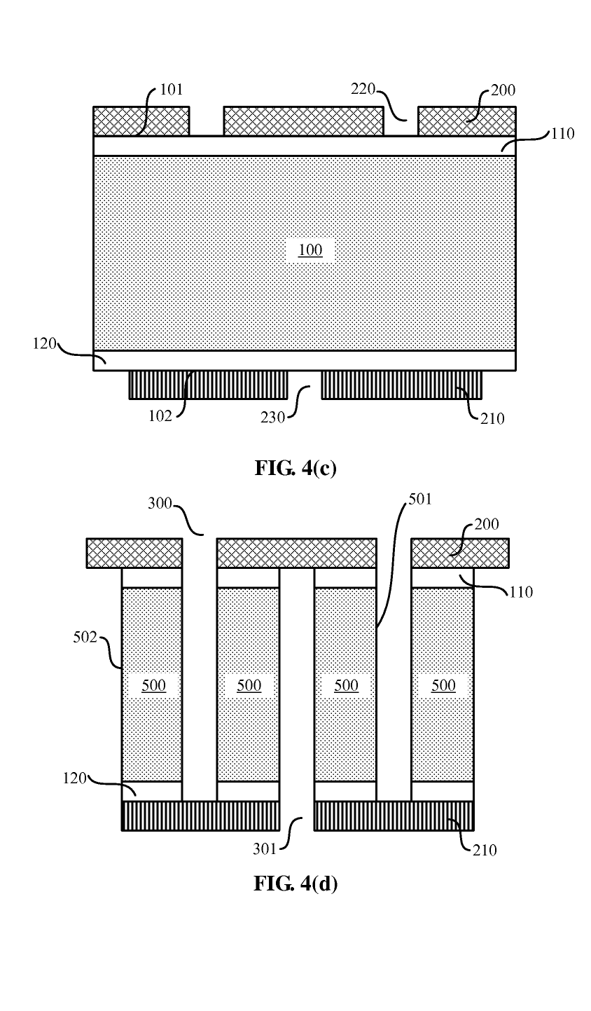

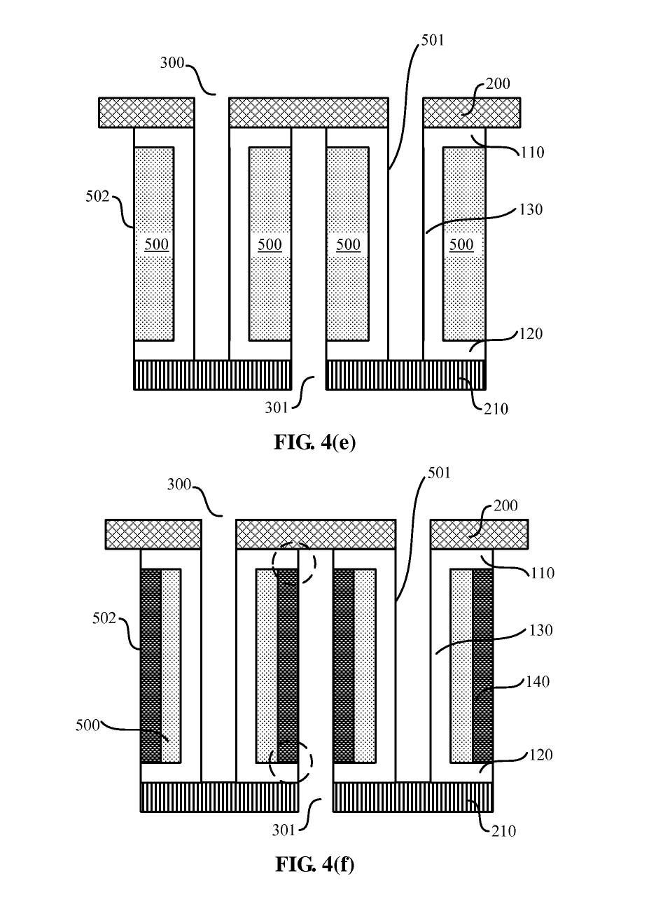

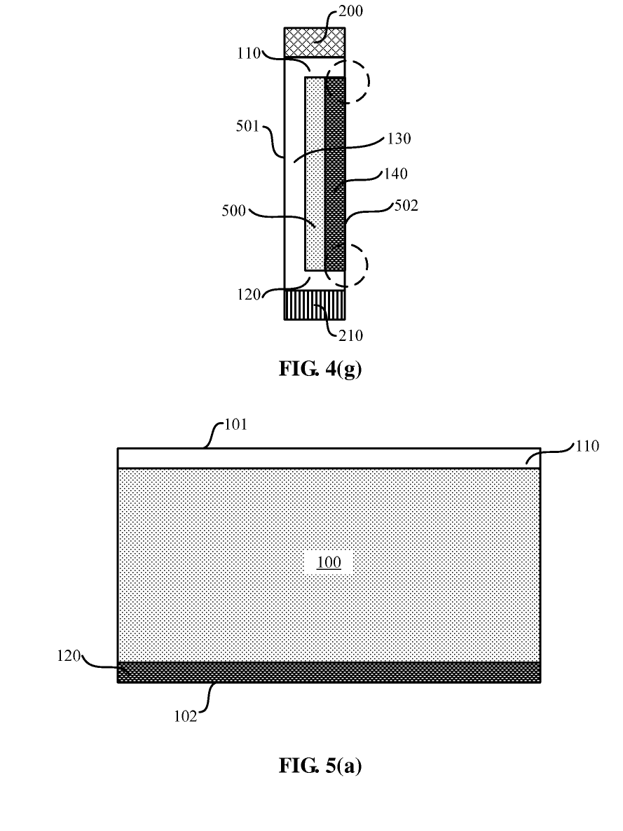

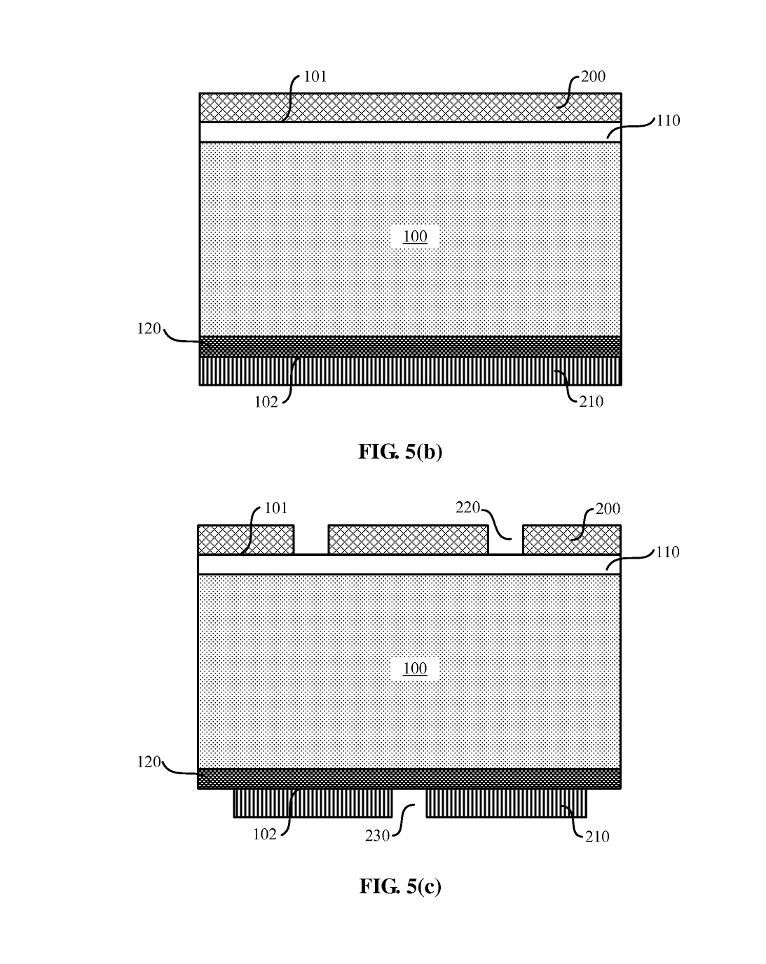

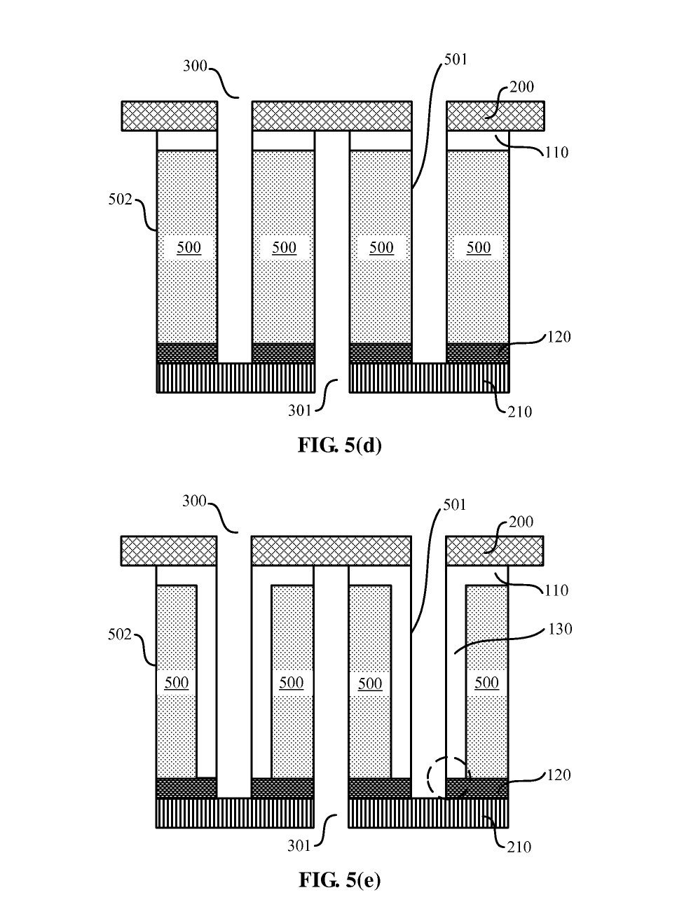

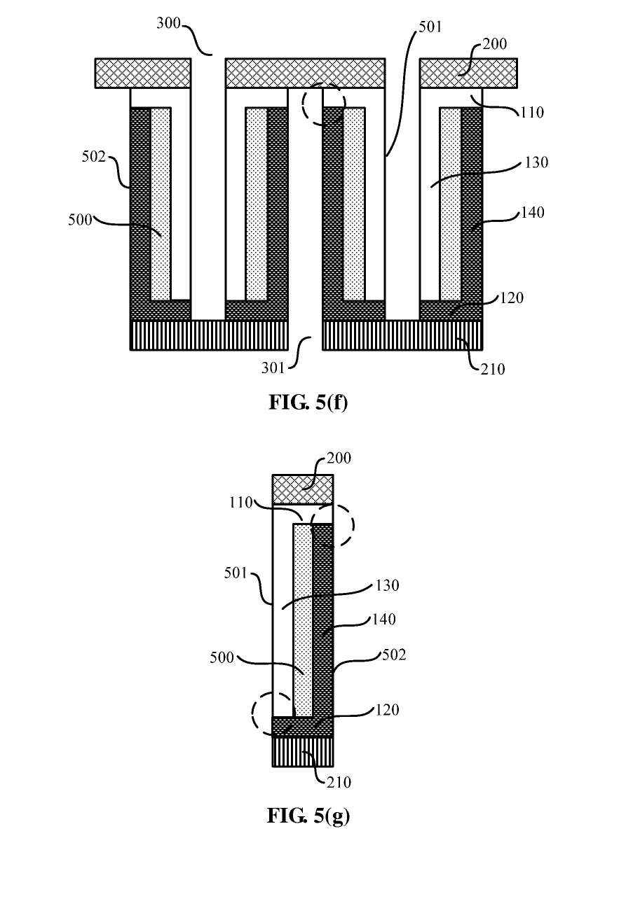

In another aspect, the present invention provides a method for manufacturing a solar cell unit, as shown in FIG. 2. Here below, details of the method for manufacturing a solar cell unit shown in FIG. 2 is elaborated in conjunction with FIGS. 3(a) and 3(b), FIG. 4(a) to FIG. 4(g), FIG. 5(a) to FIG. 5(g). FIG. 3(a) and FIG. 3(b) show respectively a top view and a cross-sectional view of a substrate used in embodiments of the present invention; FIG. 4(a) to FIG. 4(g) show cross-sectional views at each stage of forming a solar cell unit according to a preferred embodiment of the present invention; and FIG. 5(a) and FIG. 5(g) show cross-sectional views at each stage of forming a solar cell unit according to another preferred embodiment of the present invention.

At step S101, a substrate 100 is provided; wherein the substrate 100 comprises a first surface 101 and a second surface 102 opposite to the first surface 101.

Specifically, as shown in FIGS. 3(a) and 3(b), a substrate 100 is provided; wherein the substrate 100 comprises a first surface 101 and a second surface 102 opposite to the first surface 101. The material for the substrate 100 may be selected from a group consisting of monocrystalline Si, monocrystalline Ge, monocrystalline SiGe, poly Si, poly Ge, poly SiGe, amorphous Si, amorphous Ge, amorphous SiGe, compound semiconductors of III-V or II-VI group or combinations thereof. In a preferred embodiment of the present invention, the semiconductor substrate 100 comprises monocrystalline Si, monocrystalline Ge or monocrystalline SiGe. Preferably, the crystal orientation of the first surface 101 and the second surface 102 is (110) or (112). The thickness of the substrate 100 is preferably less than 1 cm.

The substrate 100 may be n-type or p-type doped. Usually, the doping concentration of impurities in the substrate 100 is smaller than 1×10¹⁷ cm⁻³.

At step S102, heavy doping is performed to the first surface 101 and the second surface 102, respectively, so as to form a first doping region 110 on the first surface 101 and to form a second doping region 120 on the second surface 102.

Specifically, as shown in FIG. 4(a) and FIG. 5(a), a first doping region 110 is formed on the first surface 101 and a second doping region 120 is formed on the second surface 102 through processing such as ion implantation, dopant diffusion by dopant sources or in-situ doped epitaxial growth. Periphery of the substrate 100 may also be doped during the doping process. However, since whether or not the periphery of the substrate is doped does not affect subsequent processes, it is not shown in FIG. 4(a) and FIG. 5(a).

In an embodiment, as shown in FIG. 4(a), the type of impurities in the first doping region 110 and the type of impurities in the second doping region 120 are the same, which is either n-type or p-type. The preferred doping type is contrary to the doping type of the substrate: if the doping type of the substrate is n-type, then the type of impurities in the first doping region 110 and in the second doping region 120 is n-type; if the doping type of the substrate is p-type, the type of impurities in the first doping region 110 and in the second doping region 120 is n-type. In this way, a PN junction is formed between the substrate 100 and the first doping region 110, the second doping region 120. This will increase junction area and enhances collection of minority carriers produced from solar radiation. This will reduce recombination of photo-generated carriers at surfaces 101 and 102. Therefore, energy conversion efficiency of the solar cell will be improved.

In another embodiment, as shown in FIG. 5(a), the type of impurities in the first doping region 110 is contrary to the type of impurities in the second doping region 120. If the type of impurities in the first doping region 110 is n-type, then the type of impurities in the second doping region 120 is p-type; if the type of impurities in the first doping region 110 is p-type, then the type of impurities in the second doping region 120 is n-type.

In respect of aforementioned two embodiments, the maximum doping concentration of impurities in the first doping region 110 and the second doping region 120 is significantly greater than the doping concentration of impurities in the substrate 100. For example, the maximum doping concentration of impurities is greater than 5×10¹⁹ cm⁻³. With dopant diffusion by dopant sources or in-situ doped epitaxial growth, the location with the maximum doping concentration is usually at the surface region. When doping is done through ion implantation, it is preferably to select such an implant energy that the maximum doping concentration is present at the surface region as defined above. Here below, detailed description is given with respect to the maximum doping concentration is present at the surface region.

Preferably, as shown in FIGS. 4(b) and 5(b), a first sheet 200 and a second sheet 210 are formed on the first surface 101 and the second surface 102, respectively, by way of, for example, deposition. The first sheet 200 and/or the second sheet 210 may be in a single-layer structure or in a multi-layer structure. The selection of materials for the sheet is related to need of etching stop effect when the substrate is etched subsequently to form deep grooves. In case the material for the substrate is selected from Si, Ge and SiGe, the material for the sheet is preferably a material layer comprising Si₃N₄, SiO₂ or combination thereof. When the sheet is in a multi-layer structure, it is appropriate to select a material for the portion (layer) in the sheet adjacent to the substrate with consideration to the need of reducing surface recombination of minority carriers according to the surface doping type. For example, if the surface doping is n-type, the material for the portion (layer) of sheet adjacent to the doping region is preferably SiN; if the surface doping is p-type, then the material for the portion (layer) of the sheet adjacent to the doping region is preferably Al₂O₃.

As shown in FIG. 4(b), in which the type of impurities in the first doping region 110 and the type of impurities in the second doping region 120 are the same, if the type of impurities in the first doping region 110 and the type of impurities in the second doping region 120 are both n-type, then SiN is a preferred material for the portion (layer) of the first sheet 200 and the second sheet 210 that is adjacent to the doping regions; if the type of impurities in the first doping region 110 and the type of impurities in the second doping region 120 are both p-type, then Al₂O₃ is a preferred material for the portion (layer) of the first sheet 200 and the second sheet 210 that is adjacent to the doping regions.

As shown in FIG. 5(b), in which the type of impurities in the first doping region 110 is contrary to the type of impurities in the second doping region 120, if the type of impurities in the first doping region 110 is n-type and the type of impurities in the second doping region 120 is p-type, then SiN is a preferred material for the portion (layer) of the first sheet 200 that is adjacent to the first doping region 110, and Al₂O₃ is a preferred material for the portion (layer) of the second sheet 210 that is adjacent to the second doping region 120; if the type of impurities in the first doping region 110 is p-type and the type of impurities in the second doping region 120 is n-type, then Al₂O₃ is a preferred material for the portion (layer) of the first sheet 210 that is adjacent to the first doping region 110, and SiN is a preferred material for the portion (layer) of the second sheet 210 that is adjacent to the second doping region 120.

At step S103, at least two first grooves 300 and at least one second groove 301 are formed from the first surface 101 and the second surface 102, respectively, wherein each of the second groove 301 is located between two neighboring first grooves 300, so as to form a vertical strip plate array comprising at least two strip plates 500 and at least one sheet.

Specifically speaking, firstly, as shown in FIG. 4(c) and FIG. 5(c), the first sheet 200 and the second sheet 210 are patterned (e.g. through lithography plus etching process) to form a first opening 220 on the first sheet 200 and to form a second opening 230 on the second sheet 210, which expose places where grooves are to be formed on the substrate 100. The first opening 220 and the second opening 230 are positioned in a staggering style. Then, as shown in FIG. 4(d) and FIG. 5(d), the substrate 100 is etched with the patterned first sheet 200 and the second sheet 210 functioning as masks, such that at least two first grooves 300 are formed from the first surface 101 of the substrate 100 and at least one second groove 301 is formed from the second surface 102 of the substrate 100. The first grooves 300 and the second groove 301 are opened in opposite directions, and each of the second groove 301 is located between two neighboring first grooves 300; the first groove and the second groove are positioned in a staggering style, which accordingly forms a vertical strip plate array comprising at least two strip plates 500 and at least one sheet. In respect of strip plates 500 in the vertical strip plate array, each has a third surface 501 and a fourth surface 502 opposite to the third surface 501. In the present embodiment, the sidewall of the first groove 300 is defined as the third surface 501 of the strip plate 500, and the sidewall of the second groove 301 is defined as the fourth surface 502 of the strip plate 500. The thickness of the strip plate 500 is usually in the range (i.e. horizontal distance between the third surface 501 and the fourth surface 502) of 10 μm-200 μm, but is not limited to this range.

In the embodiment in which the substrate 100 is monocrystalline Si and the crystal orientation of the first surface 101 and the second surface 102 is (101) or (112), the first groove 300 and the second groove 301 are etched through a wet etching process. Namely, crystal orientation of sidewalls of the first groove 300 and the second groove 301 is set to be (111) by way of controlling the direction of openings; and the substrate 100 is etched by a solution such as KOH, TMAH or EPD; since crystal orientation (111) is etched at a very slow rate, etch goes substantially vertically into the substrate so as to form substantially vertical grooves. The depth of the first groove and the second groove can be brought under control by way of controlling the concentration of the solution and the etch time. In respect of the substrate 100 with a surface bearing the first sheet 200 and the second sheet 210, the depth of the first groove 300 and the second groove 301 may be equal to the thickness of the substrate 100; in other words, the two neighboring strip plates 500 are connected through the first sheet 200 or the second sheet 210; in respect of the substrate 100 with a surface not bearing the first sheet 200 and the second sheet 210, the depth of the first groove 300 and the second groove 301 is smaller than the thickness of the substrate 100, namely, a portion of the substrate 100 is not etched, which is located at the bottom of the groove, functioning as a sheet connecting two neighboring strip plates 500. In other embodiments, dry etching or combination of wet etching and dry etching may be adopted for forming the first groove 300 and the second groove 301.

At step S104, heavy doping is performed to sidewalls of the first grooves 300 and the second groove 301, so as to form a third doping region 130 on the sidewalls of the first groove 300 and to form a fourth doping region 140 on the sidewall of the second trench 301; and the surface doping type of the first doping region 110 and the second doping region 120 is kept unchanged at the meantime, thereby forming a vertical solar cell array; the type of impurities in the third doping region 130 is contrary to the type of impurities in the fourth doping region 140.

Specifically, as shown in FIG. 4(e) and FIG. 5(e), the second groove 301 is protected such that only the first grooves 300 are exposed, which can be achieved through many different methods widely known in the prior art. For example, the second surface of the substrate can be covered with an object (e.g. an Si plate, a quartz plate or a pallet); alternatively, a protection film (e.g. SiO₂ or Si₃N₄) can be deposited on one side of the second surface. Next, the substrate 100 undergoes diffusion of dopants, such that a third doping region 130 is formed on sidewalls (i.e. the third surface 501 of the strip plate 500) of the first groove 300; the doping process may be dopant diffusion by a gas source or and in-situ doped epitaxial growth.

As shown in FIG. 4(e), the type of impurities in the third doping region 130 is the same as the type of impurities in the first doping regions 110 and the second doping regions 120.

As shown in FIG. 5(e), the type of impurities in the third doping region 130 is contrary to the type of impurities in the second doping region 120, and the maximum doping concentration in the portion of the third doping region 130, which sits close to the bottom of the first groove 300, is lower than the maximum doping concentration of the second doping region 120. In this way, the surface doping type of the second doping region 120 is kept unchanged. The portion of the third doping region 130, which sits close to the bottom of the first groove 300, and the second doping region 120 together form a PN junction (e.g. the region within the dotted lines shown in the appended drawings). The performance of the PN junction is related to the doping concentration of the portion of the third doping region 130, which sits close to the bottom of the first groove 300, and the doping concentration of the second doping region 120. For example, if a greater reverse electrical current in the PN junction is needed, it can be achieved through increasing the doping concentration of the portion of the third doping region 130, which sits close to the bottom of first groove 300, and/or the doping concentration of the second doping region 120. During a typical doping process, since it is more difficult for the dopants to get into the bottom of the first groove 300, the doping concentration in the portion of the third doping region 130, which sits close to the bottom of the first groove 300, is lower than the doping concentration in the portion thereof close to upper portion of the first groove 300; and the doping concentration difference between the bottom portion and the upper portion of the third doping region 130 may be achieved by means of adjusting doping process parameters (for example, pressure and the temperature can be tuned during dopant diffusion by gas source).

Then, as shown in FIGS. 4(f) and 5(0, the fourth doping region 140 is formed on sidewalls of the second groove 301 by means of a doping process similar to the one used to form doping region 130, so as to form a vertical solar cell array.

As shown in FIG. 4(f), the type of impurities in the fourth doping region 140 is contrary to the type of impurities in both the first doping region 110 and the second doping region 120; and the maximum doping concentration of the fourth doping region 140 is lower than the maximum doping concentrations of both the first doping region 110 and the second doping region 120, so as to keep the surface doping type of the first doping region 110 and the second doping region 120 unchanged. The portion of the fourth doping region 140 close to the bottom of the second groove 301 and the first doping region 110 together form a PN junction (e.g. the region within the dotted lines shown in the appended drawings); the performance of the PN junction is associated with both the doping concentration of the portion of the fourth doping region 140 close to the bottom of the second groove 301 and the doping concentration of the first doping region 110. For example, if a greater reverse electrical current in PN junction is needed, it can be achieved through increasing the doping concentration of the portion of the fourth doping region 140 close to the bottom of the second groove 301 and/or the doping concentration of the first doping region 110. The portion of the fourth doping region 140 close to the opening of the second groove 301 and the second doping region 120 together form a PN junction (e.g. the region within the dotted lines shown in the appended drawings); the performance of the PN junction is associated with both the doping concentration of the portion of the fourth doping region 140 close to the opening of the second groove 301 and the doping concentration of the second doping region 120. For example, if a greater reverse electrical current in PN junction is needed, it can be achieved through increasing the doping concentration of the portion of the fourth doping region 140 close to the opening of the second groove 301 and/or the doping concentration of the second doping region 120.

As shown in FIG. 5(f), the type of impurities in the fourth doping region 140 is contrary to the type of impurities in the first doping region 110; and the maximum doping concentration of the portion of the fourth doping region 140 close to bottom of the second groove 301 is lower than the maximum doping concentration of the first doping region 110, so as to keep the surface doping type of the first doping region 110 unchanged. The portion of the fourth doping region 140 close to the bottom of the second groove 301 and the first doping region 110 together form a PN junction (e.g. the region within the dotted lines shown in the appended drawings); the performance of the PN junction is associated with the doping concentration of the portion in the fourth doping region 140 close to the bottom of the second groove 301 and the doping concentration of the first doping region 110. For example, if a greater reverse electrical current in PN junction is needed, it can be achieved through increasing the doping concentration of the portion of the fourth doping region 140 close to the bottom of the groove and/or the doping concentration of the first doping region 110.

As noted from foregoing description, the type of impurities in the third doping region 130 is contrary to the type of impurities in the fourth doping region 140. Namely, if the type of impurities in the third doping region 130 is n-type, then the type of impurities in the fourth doping region 140 is p-type; if the type of impurities in the third doping region 130 is n-type, then the type of impurities in the fourth doping region 140 is p-type. The maximum doping concentration of impurities in the third doping region 130 and the fourth doping region 140 is greater than the doping concentration of impurities in the substrate 100 but is smaller than the maximum doping concentration of impurities in the first doping region 110 and the second doping region 120.

Finally, the periphery of the substrate 100 may be cut off by means of, for example, leaser beam or other cutting process, such that the vertical solar cell array is separated from the substrate 100 and the planar solar cell array is segmented into a plurality of independent solar cell units, as shown in FIG. 4(g) and FIG. 5(g). The present invention does not intend to pose limiting on other processing approaches that are also applicable for processing the vertical solar cell array.

As for the foregoing manufacturing method provided by the present invention, it exhibits following advantages:

(1) Unlike the configuration of two doping types in side surfaces of the solar cell unit provided according to the traditional art (i.e. surfaces connected to long side of the solar cell unit), the solar cell unit, which is manufactured according to the method of the present invention, has side surfaces with the same doping type; namely, the types of doping impurities in both two side faces of the solar cell unit are either n-type or p-type; or, one side surface has n-type doping impurities and the other side surface has p-type doping impurities. Accordingly, this configuration can alleviate difficulty facing the process of passivating sidewalls of the solar cell unit;
(2) Because the side surfaces of the solar cell unit has the same doping type, therefore, it becomes more convenient to put electrodes on side surfaces of the solar cell unit, and thus it becomes unnecessary to put electrodes on the light-absorbing surface of the solar cell unit. In this way, the solar cell unit is not shielded from light absorption because of shade, so that the light absorption efficiency of the solar cell unit is improved, which accordingly enhances the energy conversion efficiency of the solar cell unit;
(3) At the time of forming the first doping region 110, the second doping region 120, the third doping region 130 and the fourth doping region 140, a region (n+/p+ region) analogous to a Zener diode structure may be formed inside the solar cell unit, such that when a reverse bias is present, a relatively large electrical current may go through when the reverse bias exceeds a certain value, such that the reverse breakdown damage may be avoided. When a plurality of solar cell units are operated in series, if any one of the plurality of solar cell units cannot work properly due to shading, the region analogous to a Zener diode structure (n+/p+ region) inside the solar cell units can guarantee that the entire serial circuit operates properly.

As shown in FIG. 4(g), in case the doping concentration in the first doping region 110 (mainly the region within the dotted lines shown in the appended drawings) and the doping concentration of the fourth doping region 140 satisfy certain conditions, the PN junction formed at an area near the boundary of the first doping region 110 and the fourth doping region 140 is analogous to a Zener diode structure (n+/p+ region); likewise, in case the doping concentration in the second region 120 (mainly the region within the dotted lines in the appended drawings) and the doping concentration of the fourth doping region 140 meet certain conditions, the PN junction formed near the boundary of the second doping region 120 and the fourth doping region 140 is also analogous to a Zener diode structure (n+/p+ region). In the present embodiment, the doping concentration of the strip plate 500 of the solar cell unit is lower than 10¹⁷ cm⁻³. The first doping region 110, the second doping region 120 and the third doping region 130 have the same type of impurities, while the fourth doping region 140 has a type of impurities contrary to that of aforementioned three doping regions. The maximum doping concentration of the first doping region 110 and the second doping region 120 is greater than 5×10¹⁹ cm⁻³ (after doping, the sheet resistance at the first doping region 110 and the second doping region 120 is usually lower than 70Ω), the maximum doping concentration of the third doping region 130 and the fourth doping region 140 is usually greater than 10¹⁹ cm⁻³, but is lower than the maximum doping concentration of the first doping region 110 and the second doping region 120 (after doping, the sheet resistance of the third doping region 130 and the fourth doping region 140 is usually higher than 200Ω), such that the surfaces of the first doping region 110 and the second doping region 120 have the same doping type. In this case, the surface regions of the first doping region 110 and of the second doping region 120, which sits close to the fourth surface, keep their original doping type unchanged, even though there is compensation from doping of contrary type, such that the first doping region 110 and the second doping region 120 together may have a built-in region analogous to a Zener diode structure (n+/p+ region) (i.e. a region within the dotted lines shown in the appended drawings).

As shown in FIG. 5(g), in case the doping concentration of the first doping region 110 (mainly the region within the dotting lines in the appended drawings) and the doping concentration of the fourth doping region 140 meet certain conditions, the PN junction formed at the peripheral region near the boundary between the first doping region 110 and the fourth doping region 140 is analogous to a Zener diode structure (n+/p+ region); likewise, in case the doping concentration of the second doping region 120 (mainly the region within the dotted lines shown in the appended drawings) and the doping concentration of the third doping region 130 meet certain conditions, the PN junction formed at the peripheral region near the boundary between the second doping region 120 and the third doping region 130 is analogous to a Zener diode structure (n+/p+ region). In the present embodiment, the doping concentration of the strip plate 500 of the solar cell unit is lower than 10¹⁷ cm⁻³, the first doping region 110 and the third doping region 130 have the same doping type, the second doping region 120 and the fourth doping region 140 have the same doping type, and these two doping types are contrary to each other. The maximum doping concentration of the first doping region 110 and the second doping region 120 is greater than 5×10¹⁹ cm⁻³ (after doping, the sheet resistance at the first doping region 110 and the second doping region 120 is usually lower than 70Ω), the maximum doping concentration of the third doping region 130 and the fourth doping region 140 is usually greater than 10¹⁹ cm⁻³, but is lower than the maximum doping concentration of the first doping region 110 and the second doping region 120 (after doping, the sheet resistance of the third doping region 130 and the fourth doping region 140 is usually higher than 200Ω), such that the surfaces of the first doping region 110 and the second doping region 120 have uniform doping type. In this case, the doping type of the regions enclosed by dotted lines in the first doping region 110 and the second doping region 120 remains unchanged, even though there is compensation from doping of contrary type, such that it may configure a built-in region analogous to a Zener diode structure (n+/p+ region) together with the third doping region 130 and with the fourth doping region 140, respectively.

Noticeably, those skilled in the art should appreciate that the doping concentrations of impurities in the first doping region 110, in the second doping region 120, in the third doping region 130 and in the fourth doping region 140 are not limited to aforementioned ranges, instead, the specific values are adjustable according to needs in practice.

In another aspect, the present invention further provides a solar cell unit. With reference to FIG. 4(g) and FIG. 5(g), the solar cell unit comprises a strip plate 500, which has a third surface 501 and a fourth surface 502 opposite to the third surface 501. Wherein, the material for the strip plate 500 comprises any one selected from a group consisting of monocrystalline Si, monocrystalline Ge, monocrystalline SiGe, poly Si, poly Ge, poly SiGe, amorphous Si, amorphous Ge, amorphous SiGe, compound semiconductors of III-V or II-VI group or combinations thereof. The strip plate 500 may be p-type or n-type doped. In the present embodiment, the doping concentration of impurities in the strip plate 500 is lower than 10¹⁷ cm⁻³.

A fourth doping region 140 and a third doping region 130 are arranged on the third surface 501 and the fourth surface 502, respectively; wherein the type of impurities in the third doping region 130 is contrary to the type of impurities in the fourth doping region 140. In case the impurities in the third doping region 130 is n-type, then the impurities in the fourth doping region 140 is p-type, vice versa. The maximum doping concentration of impurities in the third doping region 130 and the fourth doping region 140 is greater than the doping concentration of impurities in the strip plate 500. In the present embodiment, the maximum doping concentration of impurities in the third doping region 130 and the fourth doping region 140 is usually higher than 10¹⁹ cm⁻³.

There are a first doping region 110 and a second doping region 120 arranged on side surfaces adjacent to the third surface 501 and the fourth surface 502. Wherein, the surfaces of the first doping region 110 and the second doping region 120 have uniform doping type. In an embodiment, as shown in FIG. 4(g), the surface doping types of the first doping region 110 and the second doping region 120 are the same, i.e., both are n-type or p-type. In another embodiment, as shown in FIG. 5(g), the surface doping type of the first doping region 110 is contrary to that of the second doping region 120. Namely, if the surface doping type of the first doping region 110 is n-type, then the surface doping type of the second doping region 120 is p-type; if the surface doping type of the first doping region 110 is p-type, then the surface doping type of the second doping region 120 is n-type. Preferably, the maximum doping concentration of impurities in the first doping region 110 and the second doping region 120 is greater than the maximum doping concentration of impurities in the third doping region 130 and the fourth doping concentration 140.

Preferably, the distance between the third surface 501 and the fourth surface 502 on the strip plate 500 is in the range of 10 μm-200 μm.

Preferably, there are a first sheet 200 and a second sheet 210 arranged on surfaces of the first doping region 110 and the second doping region 120, respectively. The first sheet 200 and/or the second sheet 210 may be in a single-layer structure, or may be in a multi-layer structure. In case the material for the substrate 100 is Si, Ge or SiGe, the first sheet 200 and/or the second sheet 210 are preferably a material layer formed by Si₃N₄, SiO₂ or combination thereof. Wherein, in case the type of impurities in the first doping region 110 is contrary to the type of impurities in the second doping region 120: if the type of impurities in the first doping region 110 is n-type and the type of impurities in the second doping region 120 is p-type, then the material for the portion (layer) of the first sheet 200 adjacent to the first doping region 110 is preferably SiN, and the material for the portion (layer) of the second sheet 210 adjacent to the second doping region 120 is preferably Al₂O₃; if the type of impurities in the first doping region 110 is p-type and the type of impurities in the second doping region 120 is n-type, then the material for the portion (layer) of the first sheet 200 adjacent to the first doping region 110 is preferably Al₂O₃, and the material for the portion (layer) of the second sheet 210 adjacent to the second doping region 120 is preferably SiN. In case the type of impurities in the first doping region 110 is same as the type of impurities in the second doping region 120: if impurities in both the first doping region 110 and the second doping region 120 are n-type, then the material for the portions (layer) of the first sheet 200 and of the second sheet 210 adjacent to the doping regions is preferably SiN; if impurities in both the first doping region 110 and the second doping region 120 are p-type, then the material for the portions (layer) of the first sheet 200 and of the second sheet 210 adjacent to the doping regions is preferably Al₂O₃.

As compared to the prior art, the solar cell unit provided according to the present invention exhibits following advantages:

(1) Instead of having two doping types at side surfaces (i.e. a surface intersecting with elongated side of a solar cell unit) of solar cell unit in the prior art, the solar cell unit provided according to the present invention has uniform doping type at its side surfaces; namely, the type of impurities in both side surfaces of the solar cell unit is either n-type or p-type, alternatively, a side surface has n-type doping impurities and the other side surface has p-type doping impurities. In this way, it effectively reduces difficulty experienced when passivating side surfaces of the solar cell unit;
(2) Since side surfaces of the solar cell unit have uniform doping type, this configuration allows electrodes on side surface of the solar cell unit instead of putting electrodes on the light-absorbing surface of the solar cell unit as it does in prior art, and avoids to cast a shade onto the solar cell unit. Therefore, the solar cell unit provided by the present invention provides improved light absorption efficiency and better energy conversion efficiency;
(3) With respect to the solar cell unit manufactured according to the present invention, when the doping concentrations of the first doping region, the second doping region, the third doping region and the fourth doping region meet certain conditions, a region analogous to a Zener diode structure (n+/p+ region) may be formed inside the solar cell unit; when a reverse bias is present, it allows flow of considerable electrical current once the reverse voltage exceeds a certain value, so as to avoid reverse breakdown damage. When a plurality of solar cell units are operated in series, if any one of the plurality of solar cell units cannot work properly due to lack of solar radiation, the region analogous to a Zener diode structure (n+/p+ region) inside the solar cell units may guarantee that the entire serial circuit operates properly.

Although the exemplary embodiments and their advantages have been described at length herein, it should be understood that various alternations, substitutions and modifications may be made to the embodiments without departing from the spirit of the present invention and the scope as defined by the appended claims. As for other examples, it may be easily appreciated by a person of ordinary skill in the art that the order of the process steps may be changed without departing from the scope of the present invention.

In addition, the scope, to which the present invention is applied, is not limited to the process, mechanism, manufacture, material composition, means, methods and steps described in the specific embodiments in the specification. According to the disclosure of the present invention, a person of ordinary skill in the art should readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

What is claimed is:

1. A method for manufacturing a solar cell unit comprises:
a) providing a substrate, which comprises a first surface and a second surface opposite to the first surface;
b) performing heavy doping to the first surface and the second surface respectively, so as to form a first doping region on the first surface and to form a second doping region on the second surface;
c) forming at least two first grooves and at least one second groove from the first surface and the second surface of the substrate; wherein each of the second groove located between two neighboring first grooves, so as to form a vertical strip plate array comprising at least two strip plates and at least one sheet;
d) performing heavy doping to sidewalls of the first groove and the second groove respectively, so as to form a third doping region on the sidewall of the first groove and to form a fourth doping region on the sidewall of the second groove; and keeping the surface doping type of the first doping region and the second doping region unchanged, so as to form a vertical solar cell array; wherein, the type of impurities in the third doping region is contrary to the type of impurities in the fourth doping region.

2. The method of claim 1, wherein the material for the substrate comprises monocrystalline Si, monocrystalline Ge or monocrystalline SiGe, and the first surface or the second surface is crystalline plane (110) or crystalline plane (112), and the sidewalls of the first groove and the second groove is crystalline plane (111).

3. The method of claim 1, wherein performing heavy doping of the same type of impurities at the first surface and the second surface.

4. The method of claim 1, wherein performing heavy doping of contrary types of impurities at the first surface and the second surface, respectively.

5. The method of claim 1, wherein the maximum doping concentration of the first doping region and the second doping region is greater than 5×10¹⁹ cm⁻³.

6. The method of claim 1 further comprising, after the step b) but prior to the step c), a step of:
e) forming a first sheet and a second sheet on the first surface and the second surface of the substrate, respectively.

7. The method of claim 6, wherein in case the type of impurities in the first doping region is contrary to the type of impurities in the second doping region:
when the type of impurities in the first doping region is n-type, and the type of impurities in the second doping region is p-type, then the material for the portion of the first sheet adjacent to the substrate is SiN, and the material for the portion of the second sheet adjacent to the substrate is Al₂O₃;
when the type of impurities in the first doping region is p-type, and the type of impurities in the second doping region is n-type, then the material for the portion of the first sheet (200) adjacent to the substrate is Al₂O₃, and the material for the portion of the second sheet adjacent to the substrate is SiN.

8. The method of claim 6, wherein in case the types of impurities in the first doping region and the second doping region are the same:
when the impurities in both the first doping region and the second doping region are n-type, then the material for the portion of the first sheet and the second sheet adjacent to substrate is SiN;
when impurities in both the first doping region and the second doping region are p-type, then the material for the portion of the first sheet and the second sheet adjacent to the substrate is Al₂O₃.

9. A solar cell unit comprising a strip plate, which has a third surface and a fourth surface opposite to the third surface; wherein, a third doping region and a fourth doping region are arranged on the third surface and the fourth surface, respectively; a first doping region and a second doping region are arranged on side surfaces adjacent to the third surface and the fourth surface; and the type of impurities in the third doping region is contrary to the type of impurities in the fourth doping region, and the surfaces of the first doping region and the second doping region have uniform doping type.

10. The solar cell unit of claim 9, wherein the strip plate is formed of monocrystalline Si, monocrystalline Ge or monocrystalline SiGe, and the side surfaces are crystalline plane (110) or (112), and the third surface and the fourth surface are crystalline plane (111).

11. The solar cell unit of claim 9, wherein the first doping region and the second doping region have impurities of the same type.

12. The solar cell unit of claim 9, wherein the type of impurities in the first doping region is contrary to the type of impurities in the second doping region.

13. The solar cell unit of claim 9, wherein:
the doping concentration at the surfaces of the first doping region and the second doping region is greater than 5×10¹⁹ cm⁻³.

14. The solar cell unit of claim 9, wherein there are a first sheet and a second sheet arranged on the surfaces the first doping region and the second doping region, respectively.

15. The solar cell unit of claim 14, wherein in case the types of impurities in the first doping region and the second doping region are the same:
when impurities in both the first doping region and the second doping region are n-type, then the material for the portion of the first sheet and the second sheet adjacent to substrate is SiN;
when impurities in both the first doping region and the second doping region are p-type, then the material for the portion of the first sheet and the second sheet adjacent to the substrate is Al₂O₃.

16. The solar cell unit of claim 14, wherein in case the type of impurities in the first doping region is contrary to the type of impurities in the second doping region:
when impurities in the first doping region are n-type, and impurities in the second doping region are p-type, then the material for the portion of the first sheet adjacent to the substrate is SiN, and the material for the portion of the second sheet adjacent to the substrate is Al₂O₃;
when impurities in the first doping region are p-type, and impurities in the second doping region are n-type, then the material for the portion of the first sheet adjacent to the substrate is Al₂O₃, and the material for the portion of the second sheet adjacent to the substrate is SiN.
